(19) United States
(12) Patent Application Publication
(10) Pub. No.: US 2026/0188379 A1
(43) Pub. Date: Jul. 2, 2026

(54) VERTICAL THREE-DIMENSIONAL (3D) DRAM ARRAY WITH DIGITLINE SELECT CIRCUITRY

(71) Applicant: Micron Technology, Inc., Boise, ID (US)

(72) Inventors: Ferdinando Bedeschi, Biassono (IT); Umberto Di Vincenzo, Capriate San Gervasio (IT); Riccardo Muzzetto, Arcore (IT)

(21) Appl. No.: 19/429,184

(22) Filed: Dec. 22, 2025

Related U.S. Application Data
(60) Provisional application No. 63/741,294, filed on Jan. 2, 2025.

(51) Int. Cl. G11C 11/408; G11C 11/4074; G11C 11/4091; G11C 11/4094; H10B 12/00; H10D 1/68

(52) U.S. Cl. CPC G11C 11/4087; G11C 11/4074; G11C 11/4091; G11C 11/4094; H10B 12/482; H10D 1/714

(57) ABSTRACT

The present disclosure includes vertical 3D DRAM array with digitline select circuitry and digitline decoupling operation, array select circuitry connected to the 3D DRAM array and methods of memory operation relating to read reference setting, read window development, and latch firing. An example memory device comprises a first array of vertically stacked memory cells and a first digitline connected to the access devices in the first array. A second digitline is connected to and decoupled from the first digitline by select circuitry. The select circuitry comprises a first digitline multiplexer and a bleed transistor. The first digitline is connected to a shared first source/drain region of the first digitline multiplexer and the bleed transistor. The select circuitry further comprises a source follower transistor and a second digitline multiplexer. The first digitline is connected to a gate of the source follower transistor. A first source/drain region of the source follower transistor is connected to a first source/drain region of the second digitline multiplexer. A second source/drain region of the source follower transistor is coupled to a power supply. A second source/drain region of the first digitline multiplexer and of the second digitline multiplexer is coupled to the second digitline. Sensing circuitry is connected to the second digitline.

### PRIORITY INFORMATION

This Application claims the benefits of U.S. Provisional Application No. 63/741,294, filed on Jan. 2, 2025, the contents of which are incorporated herein by reference.

### TECHNICAL FIELD

The present disclosure relates generally to semiconductor memory and methods, and more particularly, to apparatuses and methods related to 3D DRAM array with digitline select circuitry.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, electrically connected by the access device to a sense line, such as a digitline. The access device can be activated (e.g., to select the cell) by an access line electrically connected to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of an array of memory cells in a vertical three dimensional (3D) dynamic random access memory (DRAM) array combinable with select circuitry in accordance with a number of embodiments of the present disclosure.

FIG. 1B is a perspective view illustrating a portion of horizontal access devices and in a vertical 3D DRAM array combinable with select circuitry in accordance with a number of embodiments of the present disclosure.

FIG. 2 illustrates an embodiment of a memory cell having a horizontal access device with gate all around (GAA) structure and horizontal storage node in a vertical 3D DRAM array combinable with select circuitry in accordance with a number of embodiments of the present disclosure.

FIG. 3 is a perspective view illustrating an example embodiment of adjacent 3D DRAM arrays in a tile structure, the array having horizontally oriented, vertically stacked memory cells in a plurality of levels, combinable with select circuitry in accordance with a number of embodiments of the present disclosure.

FIG. 4 is a block diagram of vertical 3D DRAM array having select circuitry for digitline access according to one architecture and methodology for digitline access.

FIG. 5, is a block diagram of vertical 3D DRAM array having select circuitry for digitline decoupling in accordance with a number of embodiments of the present disclosure.

FIG. 6 is a schematic illustration of FIG. 5 showing select circuitry detail for digitline decoupling between 3D DRAM array vertical digitline and global digitline in accordance with a number of embodiments of the present disclosure.

FIGS. 7A and 7B are timing diagrams for a read operation in a 3D DRAM array having select circuitry for digitline decoupling in accordance with a number of embodiments of the present disclosure.

FIG. 8 is a schematic illustration of a circuit embodiment associated with the timing diagrams of FIGS. 7A and 7B showing select circuitry transistor “on”/“off” detail and signal flow operation for digitline decoupling between 3D DRAM array vertical digitline and global digitline to sense latch connection in accordance with a number of embodiments of the present disclosure.

FIGS. 9A and 9B are timing diagrams for a write operation in a 3D DRAM array having select circuitry for digitline decoupling in accordance with a number of embodiments of the present disclosure.

FIG. 10 is a schematic illustration of a circuit embodiment associated with the timing diagrams of FIGS. 9A and 9B showing select circuitry transistor “on”/“off” detail and signal flow operation for digitline decoupling between 3D DRAM array vertical digitline and global digitline to sense latch connection in accordance with a number of embodiments of the present disclosure.

FIGS. 11A and 11B are timing diagrams for a standby operation in a 3D DRAM array having select circuitry for digitline decoupling in accordance with a number of embodiments of the present disclosure.

FIG. 12 is a schematic illustration of a circuit embodiment associated with the timing diagrams of FIGS. 11A and 11B showing select circuitry transistor “on”/“off” detail and signal flow operation for digitline decoupling between 3D DRAM array vertical digitline and global digitline to sense latch connection in accordance with a number of embodiments of the present disclosure.

FIG. 13 is a schematic illustration of FIG. 12 having the additional embodiment of having a current generator connected to the second digitline of FIGS. 7-12 with select circuitry for digitline decoupling between a first and a second digitline in a 3D DRAM array, the second digitline connected to a sense latch in accordance with a number of embodiments of the present disclosure.

FIG. 14 illustrates a schematic diagram of a portion of sensing circuitry in accordance with a number of embodiments of the present disclosure.

FIG. 15 is a block diagram of an apparatus in the form of a computing system including a memory system in accordance with a number of embodiments of the present disclosure.

### DETAILED DESCRIPTION

The present disclosure includes vertical 3D DRAM array with digitline select circuitry, and methods of memory operation relating to read reference setting, read window development, and latch firing. An example memory device comprises a first array of vertically stacked memory cells and a first digitline connected to the access devices in the first array. A second digitline is connected to the first digitline by select circuitry. The select circuitry comprises a first digitline multiplexer and a bleed transistor. The first digitline is connected to a shared first source/drain region of the first digitline multiplexer and the bleed transistor. A second source/drain region of the first digitline multiplexer is connected to the second digitline. The select circuitry further comprises a source follower transistor and a second digitline multiplexer. The first digitline is connected to a gate of the source follower transistor. A first source/drain region of the source follower transistor is connected to a first source/drain region of the second digitline multiplexer. A second source/drain region of the source follower transistor is coupled to a power supply. A second source/drain region of the second digitline multiplexer coupled to the second digitline. Sensing circuitry is connected to the second digitline.

An example method of operation includes decoupling the first digitline from the second digitline, using the select circuitry, during a first memory operation and activating the second digitline through the source follower transistor. The first digitline is connected to the second digitline, using the select circuitry in a second memory operation. In one example, the first memory operation is a “read” memory operation and the second memory operation is a “write” memory operation.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure. As used herein, the designator “N,” particularly with respect to reference numerals in the drawings, indicates that a number of the particular feature so designated can be included. As used herein, “a number of” a particular thing can refer to one or more of such things (e.g., a number of memory arrays can refer to one or more memory arrays).

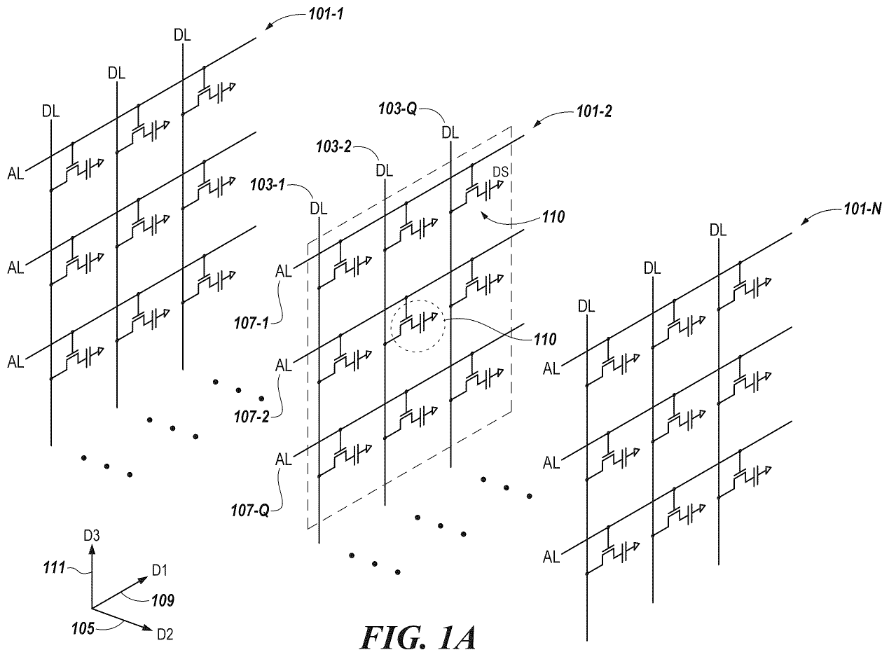

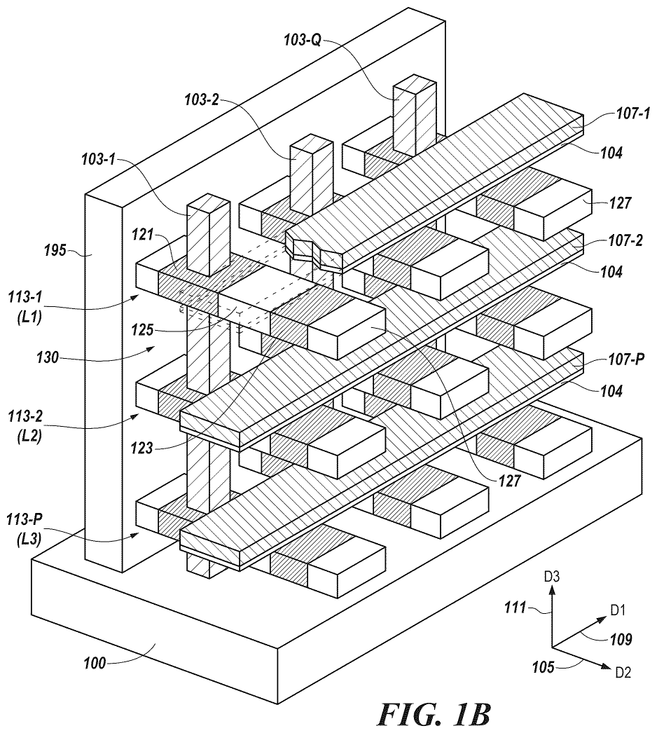

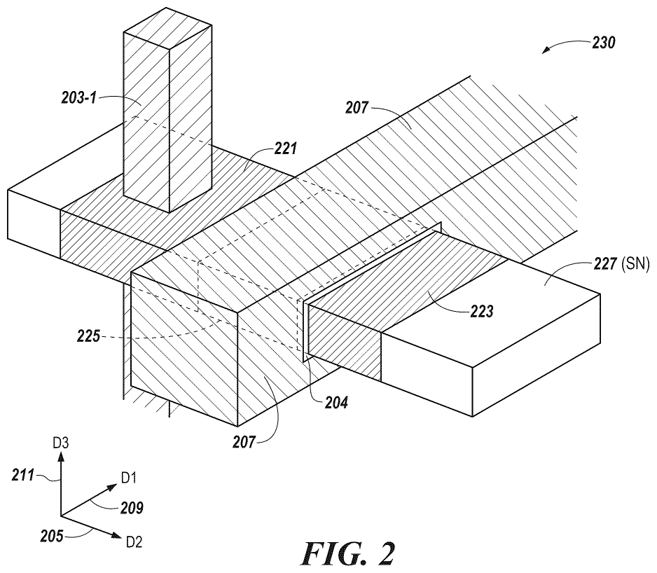

The figures herein may in some cases follow a numbering convention in which the first digit or digits correspond to the drawing figure number and the remaining digits identify an element or component in the drawing. Similar elements or components between different figures may be identified by the use of similar digits. For example, 130 may reference element “30” in FIG. 1, and a similar element may be referenced as 230 in FIG. 2. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention, and should not be taken in a limiting sense.

FIG. 1A is a schematic illustration of an array of memory cells in a vertical three dimensional (3D) dynamic random access memory (DRAM) array combinable with select circuitry in accordance with a number of embodiments of the present disclosure.

FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to a word lines). Also, each of the sub cell arrays, e.g., sub cell array 101-2, may include a plurality of digitlines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digitlines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digitlines 103-1, 103-2, . . . , 103-Q are extending in a vertical direction, e.g., third direction (D3) 111.

A memory cell, e.g., 110, may include an access device, e.g., access transistor, and a storage node located at an intersection of each access line 107-1, 107-2, . . . , 107-Q and each digitline 103-1, 103-2, . . . , 103-Q. Memory cells may be written to, or read from, using the access lines 107-1, 107-2, . . . , 107-Q and digitlines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digitlines 103-1, 103-2, . . . , 103-Q may conductively interconnect memory cells along vertical columns of each sub cell array 101-1, 101-2, . . . , 101-N. One memory cell, e.g., 110, may be located between one access line, e.g., 107-2, and one digitline, e.g., 103-2. Each memory cell may be uniquely addressed through a combination of an access line 107-1, 107-2, . . . , 107-Q and a digitline 103-1, 103-2, . . . , 103-Q.

The access lines 107-1, 107-2, . . . , 107-P may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digitlines 103-1, 103-2, . . . , 103-Q may be or include conductive patterns (e.g., metal lines) extending in a vertical direction with respect to the substrate, e.g., in a third direction (D3) 111. The digitlines in one sub cell array, e.g., 101-2, may be spaced apart from each other in the first direction (D1) 109.

According to embodiments, a gate of a memory cell, e.g., memory cell 110, may be formed by an access line, e.g., 107-2, and a first conductive node, e.g., a first source/drain region, of an access device, e.g., transistor, of the memory cell 110 may be connected to a digitline, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digitline, e.g., 103-2, and the other may be connected to a storage node.

FIG. 1B is a perspective view illustrating a portion of horizontal access devices and in a vertical 3D DRAM array for a semiconductor memory device combinable with select circuitry in accordance with a number of embodiments of the present disclosure. FIG. 1B illustrates a perspective view showing a vertical, three dimensional (3D) semiconductor memory device, e.g., a portion of a sub cell array 101-2 shown in FIG. 1A, as a vertically oriented stack of memory cells in an array, according to some embodiments of the present disclosure. As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1), a second level (L2), and a third level (L3), etc. The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . . , 107-Q connections and digitline 103-1, 103-2, . . . , 103-Q connections. The plurality of discrete components to the horizontally oriented access devices 130, e.g., transistors, may be formed in a plurality of iterations of vertically, repeating layers within each level and may extend horizontally in the second direction (D2) 105, analogous to second direction (D2) 105 shown in FIG. 1A.

The plurality of discrete components to the laterally oriented access devices 130, e.g., thin film transistors (tfts), may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, horizontally oriented double sided capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . , 107-Q may be analogous to the access lines 107-1, 107-2, . . . , 107-Q shown in FIG. 1A. The plurality of horizontally oriented access lines 107-1, 107-2, . . . , 107-Q may be arranged, e.g., “stacked”, along the third direction (D3) 111. The plurality of horizontally oriented access lines 107-1, 107-2, . . . , 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1) 113-1, (L2) 113-2, and (L3) 113-P, the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . . , 107-Q extending laterally in the first direction (D1) 109, may be formed within different vertical layers within each level. For example, the plurality of horizontally oriented access lines 107-1, 107-2, . . . , 107-Q, extending in the first direction (D1) 109, may be formed on a top surface opposing and electrically electrically connected to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . . , 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digitlines, 103-1, 103-2, . . . , 103-Q, extend in a vertical direction with respect to the substrate 100, e.g., in a third direction (D3) 111. Further, as shown in FIG. 1B, the digitlines, 103-1, 103-2, . . . , 103-Q, in one sub cell array, e.g., sub cell array 101-2 in FIG. 1A, may be spaced apart from each other in the first direction (D1) 109. The digitlines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digitlines, 103-1, 103-2, . . . , 103-Q, may vertically extend, in the third direction (D3), on sidewalls adjacent first source/drain regions 121 of respective ones of the plurality of horizontally oriented access devices 130, e.g., transistors, that are vertically stacked. In some embodiments, the plurality of vertically oriented digitlines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digitlines, e.g., 103-1, may be adjacent a sidewall of a first source/drain region 121 to a first one of the horizontally oriented access devices 130, e.g., transistors, in the first level (L1) 113-1, a sidewall of a first source/drain region 121 of a first one of the horizontally oriented access devices 130, e.g., transistors, in the second level (L2) 113-2, and a sidewall of a first source/drain region 121 a first one of the horizontally oriented access devices 130, e.g., transistors, in the third level (L3) 113-P, etc. Similarly, a second one of the vertically extending digitlines, e.g., 103-2, may be adjacent a sidewall to a first source/drain region 121 of a second one of the horizontally oriented access devices 130, e.g., transistors, in the first level (L1) 113-1, spaced apart from the first one of horizontally oriented access devices 130, e.g., transistors, in the first level (L1) 113-1 in the first direction (D1) 109. And the second one of the vertically extending digitlines, e.g., 103-2, may be adjacent a sidewall of a first source/drain region 121 of a second one of the laterally oriented access devices 130, e.g., transistors, in the second level (L2) 113-2, and a sidewall of a first source/drain region 121 of a second one of the horizontally oriented access devices 130, e.g., transistors, in the third level (L3) 113-P, etc. Embodiments are not limited to a particular number of levels.

The vertically extending digitlines, 103-1, 103-2, . . . , 103-Q, may include a conductive material, such as, for example, one of a doped semiconductor material, a conductive metal nitride, metal, and/or a metal-semiconductor compound. The digitlines, 103-1, 103-2, . . . , 103-Q, may correspond to digitlines (DL) described in connection with FIG. 1A.

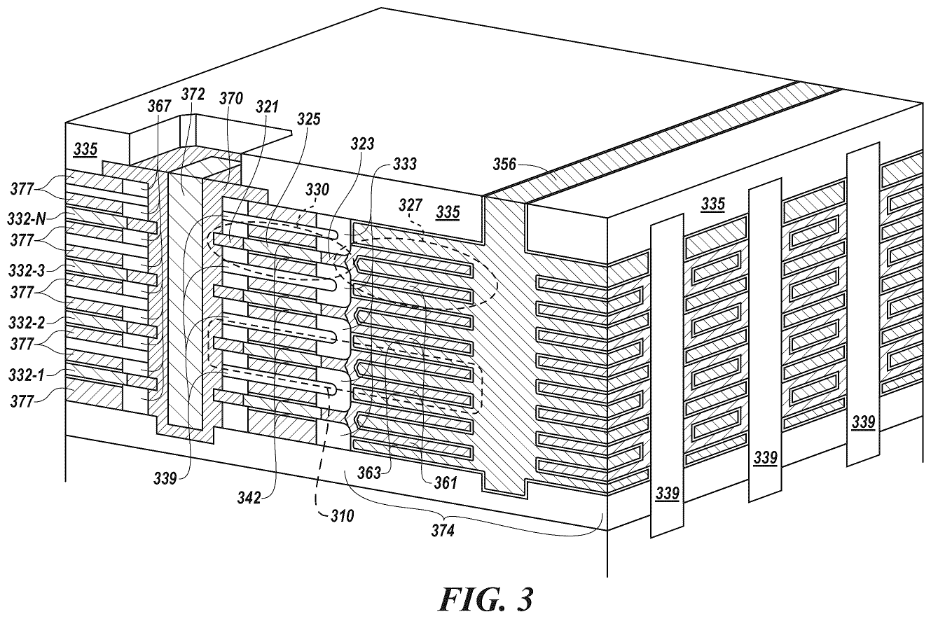

As shown in the example embodiment of FIG. 1B, a conductive body contact may be formed extending in the first direction (D1) 109 along an end surface of the horizontally oriented access devices 130, e.g., transistors, in each level (L1) 113-1, (L2) 113-2, and (L3) 113-P above the substrate 100. The body contact 196 may be connected to a body (as shown by 336 in FIG. 3) e.g., body region, of the horizontally oriented access devices 130, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates an embodiment of a memory cell having a horizontal access device with gate all around (GAA) structure and horizontal storage node in a vertical 3D DRAM array combinable with select circuitry in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p-) semiconductor material. In one embodiment, the body region and the channel 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-Q shown in FIG. 1, may disposed on a top surface opposing and electrically connected to a channel region 225, separated therefrom by a gate dielectric 204. The gate dielectric material 204 may include, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digitline, e.g., 203-1, analogous to the digitlines 103-1, 103-2, . . . , 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digitline 203-1 is formed symmetrically, in vertical alignment, in electrical contact with the first source/drain region 221. The digitline 203-1 may be formed in contact with an insulator material such that there is no body contact within channel 225.

As shown in the example embodiment of FIG. 2, the digitline 203-1 may be formed symmetrically within the first source/drain region 221 such that the first source/drain region 221 surrounds the digitline 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented transistor 230 may have a body portion which is below the first source/drain region 321 and is in contact with the body contact. An insulator material may fill the body contact such that the first source/drain region 221 may not be in electrical contact with channel 225. Further, as shown in the example embodiment of FIG. 2, an access line, e.g., 207, analogous to the access lines 107-1, 107-2, . . . , 107-Q shown in FIG. 1, may disposed all around and electrically connected to a channel region 225, separated therefrom by a gate dielectric 204.

Although the digitline 203-1 is described above as being formed symmetrically within the first source/drain region 221 such that the first source/drain region 221 surrounds the digitline 203-1 all around, embodiments are not so limited. For instance, in some examples, the digitline 203-1 can be formed asymmetrically. In this embodiment, the vertically oriented digitline is formed asymmetrically adjacent in electrical contact with the first source/drain regions 221. The digitline may be formed asymmetrically to reserve room for a body contact in the channel region 225.

FIG. 3 is a perspective view illustrating an example embodiment of adjacent 3D DRAM arrays in a tile structure, the array having horizontally oriented, vertically stacked memory cells in a plurality of levels, combinable with select circuitry in accordance with a number of embodiments of the present disclosure.

FIG. 3 shows the 3D DRAM memory cell structure 300 having horizontally oriented memory cells 310, vertically stacked in a plurality of levels, e.g., L1, L2, and L3 in FIG. 1B. The example embodiment of FIG. 3 is illustrating an array of 3D DRAM 300 having horizontally oriented memory cells 310 combinable with pitch interface layers in accordance with a number of embodiments of the present disclosure. The horizontally oriented memory cells 310 in the array 300 comprise horizontally oriented access devices 330 at each level, e.g., L1, L2, and L3 in FIG. 1B, having first source/drain regions 321 and second source/drain regions 323 separated by channel regions 325. Horizontally oriented access lines 377 form gates separated from the channel regions 325 by gate dielectric material 342. As shown in the example embodiment, horizontally oriented storage nodes 374, at each level L1, L2, and L3 in FIG. 1B, are electrically connected to the second source/drain regions 373 of the horizontally oriented access devices 330. The horizontally oriented storage nodes 374 include a first electrode 361, e.g., bottom electrode, and a second electrode 356, e.g., top electrode and/or common node, separated by a dielectric material 361. In some embodiments, the horizontally oriented storage nodes 374 are multi-sided storage nodes, e.g., double sided-capacitors, as shown in FIG. 3. Vertically oriented digitlines 370/372 are electrically connected to the first source/drain regions 321 of the horizontally oriented access devices 330. In some embodiments, a portion 370 of the vertically oriented digitlines are epitaxially formed (e.g., grown), vertically oriented digitlines 370.

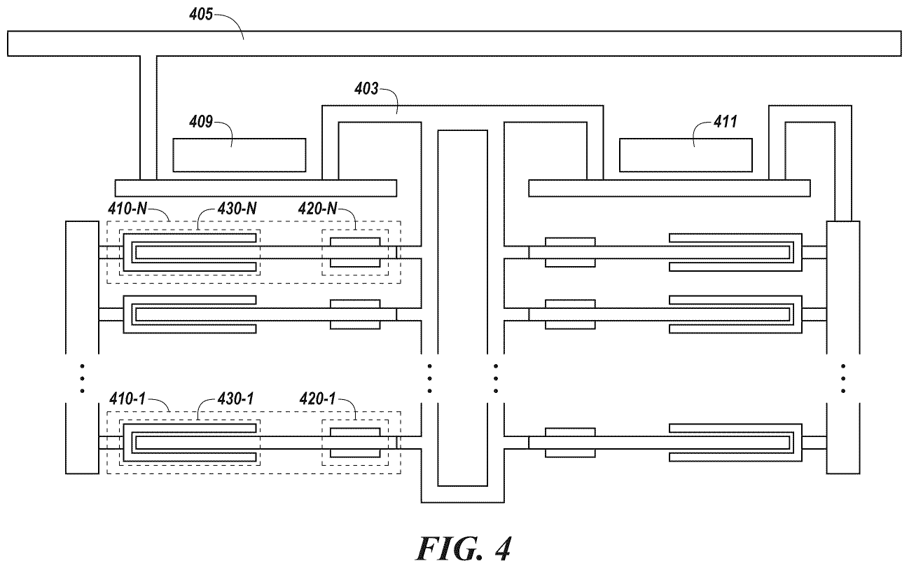

FIG. 4 is a block diagram of vertical 3D DRAM array having select circuitry for digitline access according to one architecture and methodology for digitline access. In the example of FIG. 4 a first array of vertically stacked memory cells 401, having horizontally oriented access devices and horizontally oriented storage nodes is shown adjacent a second array of vertically stacked memory cells 402, having horizontally oriented access devices, 420-1, . . . , 420-N, and horizontally oriented storage nodes, 430-1, . . . , 430-N. A vertical digitline line 403 is shared between the first array 401 and the second array 402 and electrically coupled to a source/drain region of the access devices in each array. The vertical digitline 403 is connected by select circuity 489 to a global digitline 405.

In the example of FIG. 4, the select circuitry 489 can include a first digitline multiplexer 409 and a bleed transistor 411. In the example shown in FIG. 4, the first digitline 403 is connected to a first source/drain region 413 of the first digitline multiplexer 409. A second source/drain region 415 of the first digitline multiplexer 409 is connected to a second digitline 405. The first digitline 403 is further connected to a first source/drain region 415 of a bleed transistor 411. A second source/drain region 418 of the bleed transistor 411 can be connected to a ground bias/potential (plate) 450. In some embodiments, the first digitline 403 is a vertically oriented, local digitline 403 and the second digitline 405 is a horizontally oriented, global digitline 405.

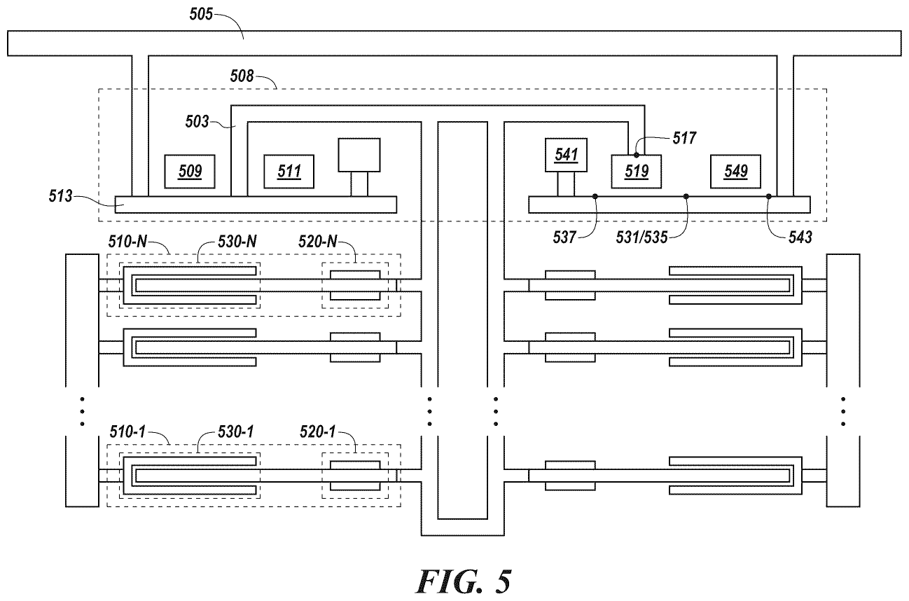

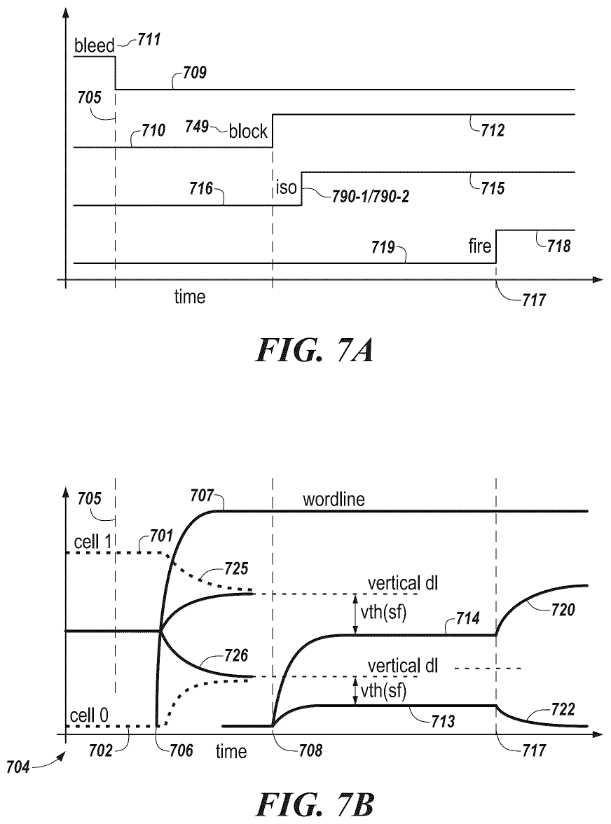

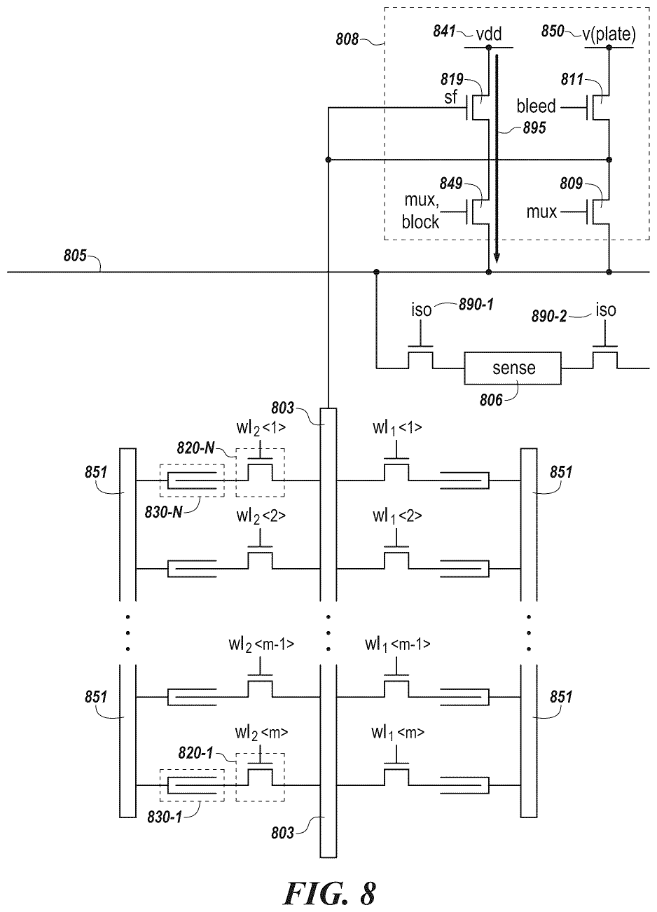

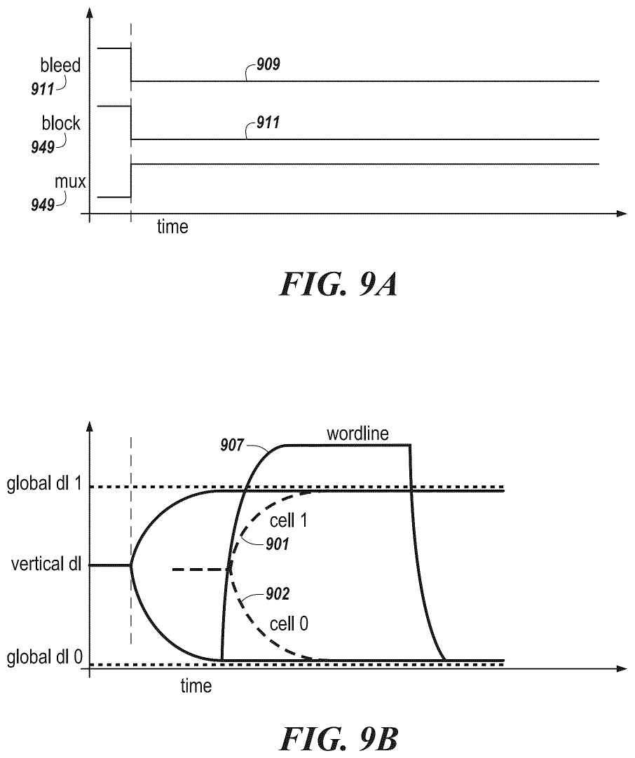

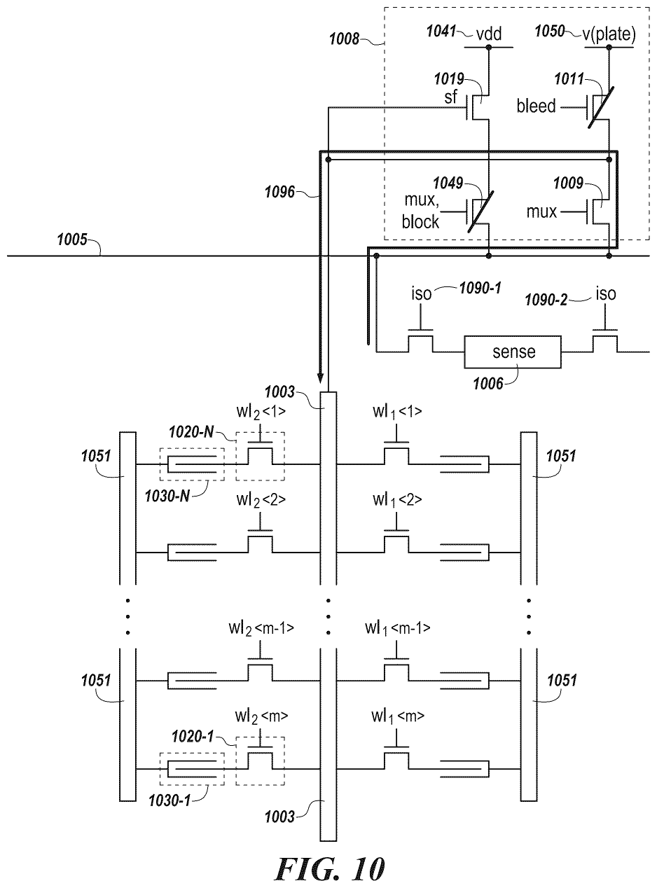

FIG. 5 is a block diagram of adjacent, vertical 3D DRAM arrays having select circuitry 508 for digitline decoupling in accordance with a number of embodiments of the present disclosure. In some embodiments the select circuitry 508 can be connected to a first digitline 503, e.g., a “local” digitline, in a first array 501 of vertically stacked memory cells, e.g., 510-1, . . . , 510-N. The first digitline 503 can be vertically connected to source/drain regions, 521-1, . . . , 521-N of access devices, 520-1, . . . , 520-N, in the first array 501 of vertically stacked memory cells. The select circuity 508 can connect and/or decouple the first digitline 503 to/from a second digitline 505, e.g., global digitline. According to embodiments, in some memory operations the select circuitry 508 is used to connect the first digitline 503 directly to the second digitline 505, and in other memory operations the select circuitry is used to decouple the first digitline 503 from the second digitline 505. For example, in a first memory operation (FIG. 7A-8), e.g., a “read” memory operation, the select circuitry 508 is used to decouple the first digitline 503 from the second digitline 505. Instead, using select circuitry 508, the second digitline 505 is activated in a decoupled manner through a source follower transistor 519. The first digitline 503 is coupled to a gate 517 of the source follower transistor 519. In a further example embodiment, in a second memory operation (FIGS. 9A-10), e.g., a “write” memory operation, the select circuitry is used to connect the first digitline 1303 directly to the second digitline 1305.

The select circuitry 508 can include a first digitline multiplexer 509 and a bleed transistor 511. In the example embodiment shown in FIG. 5, the first digitline 503 is connected to a shared first source/drain region 513 of the first digitline multiplexer 509 and the bleed transistor 511. A second source/drain region 515 of the first digitline multiplexer 509 is connected to a second digitline 505. A second source/drain region 518 of the bleed transistor 511 can be connected to a ground bias/potential (plate) 550. In some embodiments, the first digitline 503 is a vertically oriented, local digitline 503 and the second digitline 505 is a horizontally oriented, global digitline 505.

In the example embodiment of FIG. 5, the select circuitry 508 further includes a source follower transistor 519 and a second digitline multiplexer 549. As shown, the first digitline 503 is connected to a gate 517 of the source follower transistor 519. The source follower transistor 519 includes a first source/drain region 531 connected to a first source/drain region 535, e.g., as a shared source/drain region, of the second digitline multiplexer 549. A second source/drain region 537 of the source follow transistor 519 is connected to a power supply 541. A second source/drain region 543 of the second digitline multiplexer 549 is connected to the second digitline 505. The second digitline 505 can be connected to sensing circuitry as shown in FIGS. 8, 10, and 12.

As shown in the embodiment of FIG. 5, in some embodiments the first array 501 of vertically stacked memory cells, e.g., 510-1, . . . , 510-N can be located horizontally adjacent to a second array 502 of vertically stacked memory cells, e.g., 511-1, . . . , 511-N. In some embodiments, the first array 501 and the second array 502 of vertically stacked memory cells can include horizontally oriented access devices, e.g., 520-1, . . . , 520-N and horizontally oriented storage nodes, e.g., 530-1, . . . , 530-N. In this example embodiment, the first digitline 503 is a vertically oriented digitline 503 and is shared between the first and the second arrays, 501 and 502, and connected to access devices, e.g., 520-1, . . . , 520-N, in the first and the second arrays, 501 and 502. As shown in the example embodiment of FIG. 5, the first digitline multiplexer 509 and the bleed transistor 511 can be located, e.g., formed in a semiconductor fabrication process, vertically above the first array 501, and the source follower transistor 519 and the second digitline multiplexer 549 can be located, e.g., formed in a semiconductor fabrication process, vertically above the second array 502.

In some embodiments, the source follower transistor 519 and the second digitline multiplexer 549 are thin film transistors. In some embodiments the horizontally oriented access devices, e.g., 520-1, . . . , 520-N, are thin film transistors (tfts) and are connected to the horizontally oriented storage nodes 530-1, . . . , 530-N. In some embodiments, as shown in FIG. 2, the horizontally oriented access devices, e.g., 520-1, . . . , 520-N, include a gate all around structure (GAA). In some embodiments, as shown in FIG. 3, the horizontally oriented storage nodes, 530-1, . . . , 530-N are double sided capacitors. In some embodiments, as shown in FIG. 3, the first digitline 503 is a multilayer, vertical digitline. In some embodiments, as shown in FIG. 3, each layer, e.g., 370 and 372 in FIG. 3, of the multilayer, first digitline 503 has a different conductive material composition, e.g., doped polysilicon, tungsten (W), titanium nitride (TiN), etc. In some embodiments, the first and the second arrays, 501 and 502, have horizontal access lines, as shown in FIGS. 2 and 3.

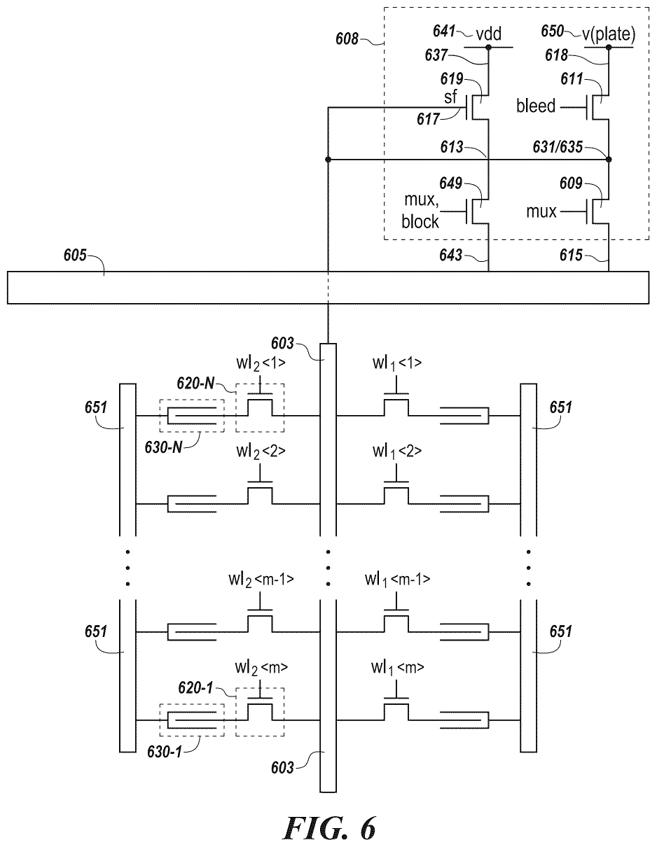

FIG. 6 is a schematic illustration of FIG. 5 showing select circuitry detail for digitline decoupling between a vertical digitline and a global digitline in a 3D DRAM array in accordance with a number of embodiments of the present disclosure. As shown in FIG. 6, a first digitline 603 is shared between two adjacent vertical DRAM arrays 601 and 602. The shared, vertical first digitline 603 is connected to source/drain regions of access devices, 620-1, . . . , 620-N, for memory cells, 610-1, . . . , 610-N, of both adjacent, vertically stacked 3D DRAM arrays 601 and 602. As shown in FIG. 6, the vertical first digitline 603 is connected to and/or decoupled from a second digitline 605 by select circuitry 608.

The select circuitry 608 can include a first digitline multiplexer 609 and a bleed transistor 611. In the example embodiment shown in the schematic illustration of FIG. 6, the first digitline 603 is connected to a shared first source/drain region 613 of the first digitline multiplexer 609 and the bleed transistor 611. A second source/drain region 615 of the first digitline multiplexer 609 is connected to a second digitline 605. A second source/drain region 618 of the bleed transistor 611 can be connected to a ground bias/potential (plate) 650. In some embodiments, the first digitline 603 is a vertically oriented, local digitline 603 and the second digitline 605 is a horizontally oriented, global digitline 605.

In the schematic example embodiment of FIG. 6, the select circuitry 608 further includes a source follower transistor 619 and a second digitline multiplexer 649. As shown, the first digitline 603 is connected to a gate 617 of the source follower transistor 619. The source follower transistor 619 includes a first source/drain region 631 connected to a first source/drain region 635, e.g., as a shared source/drain region, of the second digitline multiplexer 649. A second source/drain region 637 of the source follow transistor 619 is connected to a power supply 641. A second source/drain region 643 of the second digitline multiplexer 649 is connected to the second digitline 605. The second digitline 605 can be connected to sensing circuitry as shown in FIGS. 8, 10, and 12.

FIGS. 7A and 7B are timing diagrams for a read operation in a 3D DRAM array having select circuitry for digitline decoupling in accordance with a number of embodiments of the present disclosure. FIG. 8 is a schematic illustration of FIGS. 7A and 7B showing select circuitry transistor “on”/“off” detail and signal flow operation for digitline decoupling between a vertical digitline and a global digitline in a 3D DRAM array. The global digitline being connected to a sense amplifier (e.g., sense latch 806 in FIG. 8) in accordance with a number of embodiments of the present disclosure.

In some embodiments, the method is for a first memory operation, e.g., “read” memory operation, using select circuitry to decouple a first digitline from a second digitline using a source follower transistor, a first digitline multiplexer, and a second digitline multiplexer in association with a vertically stacked three-dimensional (3D) dynamic random access memory (DRAM) array. In FIG. 7A, the timing diagram graph illustrates a change in applied potential to a gate of an access device (control signal), such as a thin film transistor, to enable, e.g., “turn on” signal high a particular access device, or disable, e.g., “turn off” signal low the particular access device. As such the vertical axis, y-axis, illustrates applied voltage potential level, e.g., magnitude, and the horizontal axis, x-axis, illustrates chronological timing sequence.

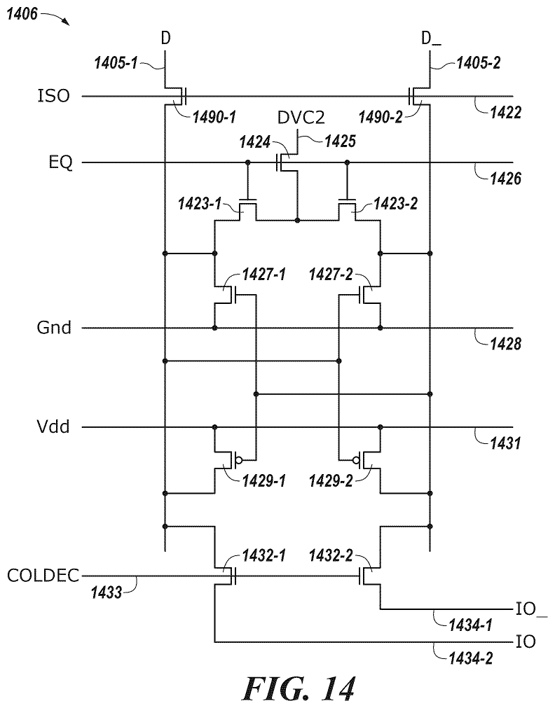

In FIG. 7A a change in applied potential, e.g., up and down between high and low signals, can be illustrated as transitioning from a standing state of applied potential over time, and these applied signals are illustrated in the example for a bleed transistor 711 control signal, a second digitline multiplexer (“block”) 749 control signal (e.g., 549 and 649 in FIGS. 5 and 6), isolation transistors (iso) 751 control signal (e.g., 851-1 and 851-2 in FIG. 8 and also shown in FIGS. 10, 12, and 14) as associated with a sense amplifier access/connection, and a sense amplifier activation (fire) control signal at 717 between signals 719 and 718, as described more in connection with FIG. 14.

The timing graph of FIG. 7B illustrates a signal magnitude represented as a voltage level on the vertical y-axis, and changes to the signal magnitude over time, chronologically, on the x-axis corresponding to FIG. 7A's control signals in association with a read operation.

As shown in FIG. 7A, initially the bleed transistor 711 is enabled, e.g., “on”, and creates and conduction path to ground the first digitline, e.g., 803 in FIG. 8, connecting the first digitline to a ground plate, 850 in FIG. 8, to clear the digitline from previous memory operations. Initially, as shown in FIG. 7B, the state of the memory cell storage node, e.g., capacitor, in the read operation of an addressed memory may store information in the form of a bit, e.g., a “1” or “0”. This “bit” of information, “1” or “0”, may be represented by the presence or absence of a charge (potential) held by the capacitor. In one example embodiment, the potential 701, e.g., cell 1, can be indicative of a stored charge, e.g., a “1” bit. In this example, the potential 702, e.g., cell 0, can be indicative of the absence of a stored charge, e.g., a “0” bit. As explained in FIG. 14, a potential 703 can applied to a complementary pair of first digitlines, e.g., 501 in FIG. 5, to equilibrate the complementary pair of first digitlines to approximately half the difference between a stored charge, e.g., “1” bit, and that of an absence of stored charge, e.g., “0” bit. This initial state to the read operation is illustrated on the far left of the lower graph at the start (time 0) 704 in the embodiment of a read operation shown in the timing diagrams of FIGS. 7A and 7B.

In one embodiment, the first digitline multiplexer, 809 in FIG. 8, is disabled, e.g., turned off. That is, the gate potential applied to a gate of the first digitline multiplexer 809 is transitioned to a low state, e.g., 710 in FIG. 7A, to isolate a second digitline, 805 in FIG. 8, from the first digitline 803. As described above, the first digitline, 803 in FIG. 8, is connected to a shared source/drain region for the first digitline multiplexer (809 in FIG. 8) and the bleed transistor 711 (811 in FIG. 8). As shown in FIG. 7A, at 705 the gate potential applied to a gate of the bleed transistor 711 is transitioned to a “low” state 729, e.g., the bleed transistor is disabled.

Next, as shown in FIG. 7B, at 706 an access line connected to a gate of an addressed cell is fired. Firing an addressed access line, e.g., first access line, applies a potential 707 to all gates connected to that access line, enabling associated access devices. As shown in FIG. 7B, at 706 the access line, e.g., wordline, is fired resulting in an increase 707 in the applied potential to that access line.

Firing the first access line associated with an address in the 3D DRAM array enables charge sharing from a storage node, e.g., 830-1, . . . , 830-N, in FIG. 8, addressed through an associated access device, 820-1, . . . , 820-N, etc. in FIG. 8, to the first digitline, 803 in FIG. 8. As shown in the schematic of FIG. 8, the first digitline 803 is connected to a gate 817 of a source follower transistor 819 having a shared, first source/drain region 831/835 connected to a second digitline multiplexer 849. A second source/drain region 837 of the source follow transistor 819 is connected to a power supply 841. Thus, firing the first access line associated with an address in the 3D DRAM results in charge sharing with an associated first digitline, e.g., 803 in FIG. 8. This results in pulling “up” 725 or “down” 726 a potential on the first digitline 803, shown as Cell 1 or Cell 0 in FIG. 7B, depending on the charge held on the addressed storage node, e.g., a “1” or “0” information state (“bit”). The charge sharing with the associated first digitline results in enabling, e.g., turning “on”, an associated source follower transistor, 819 in FIG. 8, by applying a potential to the gate of the source follower, using the charge shared from the storage node, through the access device, e.g., 820-1, . . . , 820-N, to the first digitline 803.

As shown in FIG. 7A at 708, the second digitline multiplexer (e.g., “block” transistor), 849 in FIG. 8, is enabled. In FIG. 7A this is illustrated in the applied potential to the block transistor 749 transitioning to a “high” state 712 from a “low” state 710. As shown in FIG. 7B, this results in biasing a second digitline, 805, e.g., global digitline, by connecting to a power supply 841, Vdd, and conducting through the source follower transistor 819 and the second digitline multiplexer 849 (e.g., block transistor 849) to the second digitline 805. The power supply 841 is connected at the second source/drain 837 of the source follower transistor 819 and the second digitline is connected to a second source/drain region 843 of the block transistor 849. Hence the second digitline 805 is coupled to the first digitline 803 through the source follower transistor 819.

As shown in FIG. 7B, a potential on the second digitline 805 is then raised to either a first level 714 or a second level 713, depending on the charge held on the addressed storage node, e.g., a “1” or “0” information state (“bit”). Next, as shown at 714 in FIG. 7A, isolation gate transistors (iso) 821-1 and 821-2 are turned “off”. When a “high” state potential is applied to gates of isolation transistors (iso), 851-1 and 851-2 in FIG. 8, e.g., the iso transistors are enabled and turned “on” and the iso transistors 851-1 and 851-2 connect the second digitline 805 to the sense amplifier circuit 806. Thus, in FIG. 7A, when a potential applied to the gates of isolation transistors (iso), 851-1 and 521-2 in FIG. 8, which connect a second digitline 805 to a sense amplifier circuit 806, are transitioned to a “high” applied state 715, e.g., enable, from a “low” applied state 716, the isolation transistors 890-1 and 890-2 switch “on” and connect the second digitline 805 to the sense amplifier circuit 806. In this manner, the select circuitry 808 has resulted in the sense circuit 806 being connected to the second digitline 805 and disconnected from the first digitline 803 capacitance. Operation of the sense amplifier circuit 806, including sampling of a reference potential, Vref, is explained in further detail in connection with FIG. 14.

Next, using select circuitry embodiments as described herein for a read operation, the sense amplifier circuit 806 is then fired, e.g., enabled, with more detail described further connection with FIG. 14. Firing the sense amplifier circuit is shown in FIG. 7A at 717 by a “high” signaling potential applied to the sense amplifier circuit 806, enabling the sense amplifier 806 circuit by transitioning to a “high” state 718 from a “low” signal state 719. As shown in FIG. 7B, this results in either pulling further “up” 720 or further “down” 722 a potential on the second digitline 805 to either an illustrated higher potential third level 720 or a lower potential fourth level 722, depending on the charge originally being held on the addressed storage node, e.g., a “1” or “0” information state (“bit”).

As stated above, FIG. 8 is a schematic illustration of FIGS. 7A and 7B showing select circuitry transistor “on”/“off” detail and signal flow operation for digitline decoupling between 3D DRAM array vertical digitline, e.g., first digitline, 803 and global digitline, e.g., second digitline 805 with sense latch 806 connection in accordance with a number of embodiments of the present disclosure. As shown in the schematic embodiment of FIG. 8, firing the first access line associated with an address in the 3D DRAM array enables charge sharing from a storage node, e.g., 830-1, . . . , 830-N, in FIG. 8, addressed through an associated access device, 820-1, . . . , 820-N, etc. in FIG. 8, to the first digitline, 803 in FIG. 8. As shown in the schematic of FIG. 8, the first digitline 803 is connected to a gate 817 of a source follower transistor 819 having a shared, first source/drain region 831/835 connected to a second digitline multiplexer 849. A second source/drain region 837 of the source follow transistor is connected to a power supply 841.

Thus, firing the first access line associated with an address in the 3D DRAM results in charge sharing with an associated first digitline, e.g., 803 in FIG. 8. This results in pulling “up” or “down” a potential on the first digitline 803, shown as Cell 1 or Cell 0 in FIG. 7B, depending on the charge held on the addressed storage node, e.g., a “1” or “0” information state (“bit”). The bleed transistor 811 is “off”. The first digitline multiplexer 809 is “off”. The charge sharing with the associated first digitline 803 results in enabling an associated source follower transistor, 819 in FIG. 8, by applying a potential to the gate of the source follower, using the charge shared from the storage node, through the access device to the first digitline, e.g., 820-1, . . . , 820-N. As shown in the example read operation embodiment of FIG. 8, the source follower transistor 819 is “on” and connected to a power supply, Vdd, 841. The second digitline multiplexer 849 is “on” and connected to the source follower transistor 819 and the second digitline 805. Hence, the power supply potential is conducted as a signal to the second digitline 805 according to the path shown as 895, decoupling the capacitance between the first digitline 803 and the second digitline 805. Thus, according to embodiments described herein and shown in FIGS. 7A-8, using select circuitry 808 to decouple the first digitline 803 from the second digitline 805 comprises decoupling the first digitline 803 from the second digitline 805 during a “read” operation.

FIGS. 9A and 9B are timing diagrams for a write operation in a 3D DRAM array having select circuitry for digitline decoupling in accordance with a number of embodiments of the present disclosure. FIG. 10 is a schematic illustration of a circuit embodiment associated with the timing diagrams of FIGS. 9A and 9B showing select circuitry transistor “on”/“off” detail and signal flow operation for digitline decoupling between 3D DRAM array vertical digitline and global digitline to sense latch connection in accordance with a number of embodiments of the present disclosure. As noted above, embodiments include methods for memory operation using select circuitry to decouple a first digitline from a second digitline the through a first digitline multiplexer and a second digitline multiplexer in association with a vertically stacked three-dimensional (3D) dynamic random access memory (DRAM) array.

In FIG. 9A, the timing diagram graph illustrates a change in applied potential to a gate of an access device (control signal), such as a thin film transistor, to enable, e.g., “turn on” signal high, a particular access device, or disable, e.g., “turn off” signal low, the particular access device. As above in FIGS. 7A and 7B, the vertical axis, y-axis, illustrates applied voltage potential level, e.g., magnitude, and the horizontal axis, x-axis, illustrates chronological timing sequence.

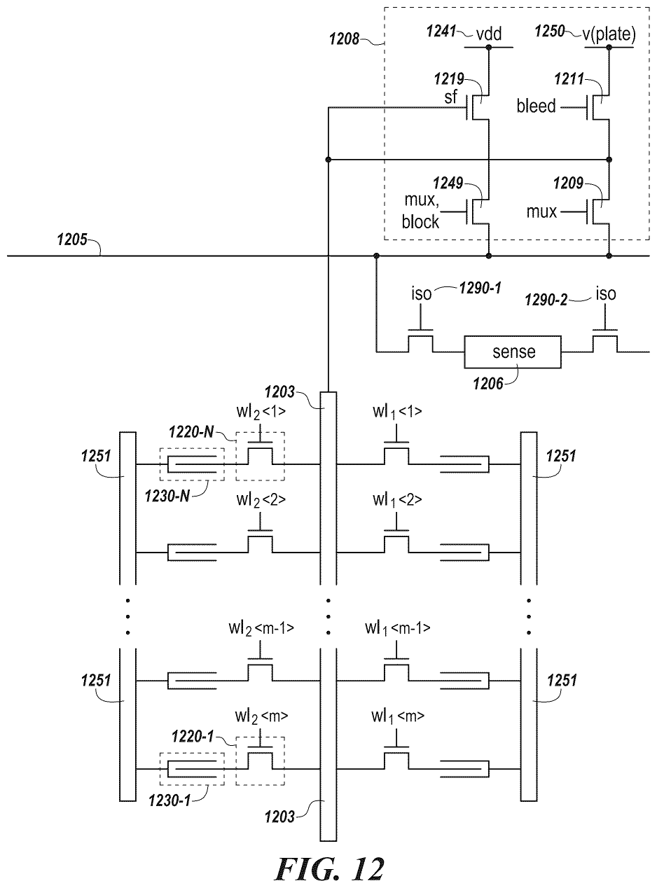

In FIG. 9A a change in applied potential, “up” and “down” in magnitude/value, e.g., “high” and “low” signals, is illustrated transitioning from a standing state of the particular applied potential over time, and these applied signals are illustrated in the example for a bleed transistor 911 control signal, a second digitline multiplexer (“block”) 949 control signal (e.g., 549 and 649 in FIGS. 5 and 6), isolation transistors (iso) 951 control signal (e.g., 1051-1 and 1051-2 in FIG. 10 and also shown in FIG. 12, and 14) as associated with a sense amplifier access/connection, and a sense amplifier activation (fire) control signal, as described more in connection with FIG. 14.

The timing diagram graph of FIG. 9B illustrates a signal magnitude represented as a voltage level on the vertical y-axis, and changes to the signal magnitude over time, chronologically, on the horizontal x-axis corresponding to the upper graph's control signals in association with a write operation.

As shown in FIG. 9A, initially the bleed transistor 911 is enabled, e.g., “on”, and creates and conduction path to ground the first digitline, e.g., 1003 in FIG. 10, connecting the first digitline to a ground plate, 1050 in FIG. 10, to clear the digitline from previous memory operations.

Initially, as shown in FIG. 9B, the state of the second digitline, e.g., global digitline shown as 1005 in FIG. 10, in the write operation of an addressed memory location may retain a state of “high” or “low” from a previous access, e.g., read operation, in the form of a high potential 901, e.g., a “cell 1”, or in the form of a low potential 902, e.g., “cell 0”. As such, a potential 903 applied to a complementary pair of first digitlines, e.g., 501 in FIG. 5, is equilibrated to approximately half the difference between a charge to store “1” and that of an absence of a charge to store “0”. This initial state to the write operation is illustrated on the far left of FIG. 9B at the start 904 (time 0) in the embodiment of a write operation shown in the timing diagrams of FIGS. 9A and 9B.

In one embodiment, the first digitline multiplexer, 1009 in FIG. 10, is enabled, e.g., turned “on”. That is, the gate potential applied to a gate of the first digitline multiplexer 1009 is transitioned to a high state, e.g., 909 in FIG. 9A, to connect a second digitline, 1005 in FIG. 10, to the first digitline 1003. As described above, the first digitline, 1003 in FIG. 10, is connected to a shared source/drain region for the first digitline multiplexer (1009 in FIG. 10) and the bleed transistor 911 (1011 in FIG. 10). As shown in FIG. 9A, at 905 the gate potential applied to a gate of the bleed transistor 911 is transitioned to a “low” state, e.g., the bleed transistor is disabled, so that the bleed transistor switches off to disconnect the first digitline 1003 from a ground plate 1050. And, at 905 the gate potential applied to the first digitline multiplexer 909 is transitioned to a “high” state, and the gate potential applied to the second digitline multiplexer 949, e.g., “block” transistor, is transitioned to a “low” state so that the source follower transistor 919 is disabled.

Next, as shown in FIG. 9B, at 906 an access line connected to a gate of an addressed cell is fired. Firing an addressed access line, e.g., first access line, applies a potential 907 to all gates connected to that access line, enabling associated access devices. As shown in FIG. 9B, at 906 the access line, e.g., wordline, is fired resulting in an increase 907 in the applied potential to that access line.

Firing the first access line associated with an address in the 3D DRAM array enables charge sharing from a second digitline 1005 in FIG. 10, addressed through the enabled first digitline multiplexer 1009 to the first digitline 1003 and to a storage node, e.g., 1030-1, . . . , 1030-N associated with the addressed access device, 1020-1, . . . , 1020-N, etc. enabled by the first access line. As shown in the schematic of FIG. 10, the first digitline 1003 is connected to a gate 1017 of a source follower transistor 1019 having a shared, first source/drain region 1031/1035 connected to a second digitline multiplexer 1049 (“block”), which is switched off. Thus, firing the first access line associated with an address in the 3D DRAM results in charge sharing through the first digitline multiplexer 1009 to the first digitline 1003 and to a storage node, e.g., capacitor cells 1030-1, . . . , 1030-N pulling “up” 925 or “down” 926 a potential on a capacitive cell 1030-1, . . . , 1030-N, shown as Cell 1 or Cell 0 in FIG. 9B, depending on the charge state addressed to a particular storage node, e.g., a “1” or “0” information state (“bit”). Disabling the block transistor 949, 1049 in FIG. 10, disables the associated source follower transistor, 1019 in FIG. 10 having its second source/drain region couple to a power supply, Vdd, 1041.

As shown in FIG. 9B, at 908 the applied potential on the fired access line is removed and the addressed capacitive cell 1030-1, . . . , 1030-N, shown as Cell 1 or Cell 0 retains a stored state depending storage information being written, e.g., raised to either a first level 912 or a second level 913 depending on the “1” or “0” information state (“bit”).

During a write operation, isolation gate transistors (iso) 1021-1 and 1021-2 are turned “on”. When a “high” state potential is applied to gates of isolation transistors (iso), 1021-1 and 1021-2 in FIG. 10, e.g., the iso transistors are enabled and turned “on” and the iso transistors 1021-1 and 1021-2 to connect the second digitline 1005 to the sense amplifier circuit 1006. As explained in FIG. 14, is sense amplifier circuit 1006 is fired and a “1” or a “0” data state is written from the second digitline 1005 to the first digitline 1003 through the first digitline multiplexer 1009 and to a storage node, e.g., 1030-1, . . . , 1030-N, through a respective addressed access device, 1020-1, . . . , 1020-N, e.g., the sense amplifier circuit 1006 writes data, biasing the second digitline 1005 to ground or power supply, Vdd. This conduction path is shown as 1096 in FIG. 10. Using select circuitry 1008 embodiments as described herein for a read operation, the sense amplifier circuit 1006 is fired, e.g., enabled, with more detail described further connection with FIG. 14. Firing the sense amplifier circuit results in either pulling further “up” or further “down” a potential on the second digitline 1005 to either higher potential third level 1020 or a lower potential fourth level 1022, depending on a state, e.g., charge, being written to an addressed storage node, e.g., a “1” or “0” information state (“bit”).

As stated above, FIG. 10 is a schematic illustration of an embodiment of the timing diagrams shown in FIGS. 9A and 9B showing select circuitry transistor “on”/“off” detail and signal flow operation for digitline decoupling between 3D DRAM array vertical digitline, e.g., first digitline, 1003 and global digitline, e.g., second digitline 1005 with sense latch 1006 connection in accordance with a number of embodiments of the present disclosure. As shown in the schematic embodiment of FIG. 10, firing the first access line associated with an address in the 3D DRAM array enables charge sharing from a second digitline 1005 through an enabled first digitline multiplexer 1009 to a storage node, e.g., 1030-1, . . . , 1030-N addressed through an associated access device, 1020-1, . . . , 1020-N. As shown in the schematic of FIG. 10, the first digitline 803 is connected to the second digitline 1005 through the enabled first digitline multiplexer 1009.

Thus, according to embodiments described herein and shown in FIGS. 9A-10, using select circuitry 1008 to connect the first digitline 1003 to the second digitline 1005 includes connecting the first digitline 1003 to the second digitline 1005 during a write operation as shown by conduction path 1096.

As described, the method includes using select circuitry 1008 to connect the first digitline 1003 the second digitline 1005 by disabling the bleed transistor 1011 and the second digitline multiplexer 1049, as shown in FIG. 10, and enabling the isolation transistors, connecting the second digitline 1005 to the sense amplifier 1006, and enabling the first digitline multiplexer 1009 during a write operation.

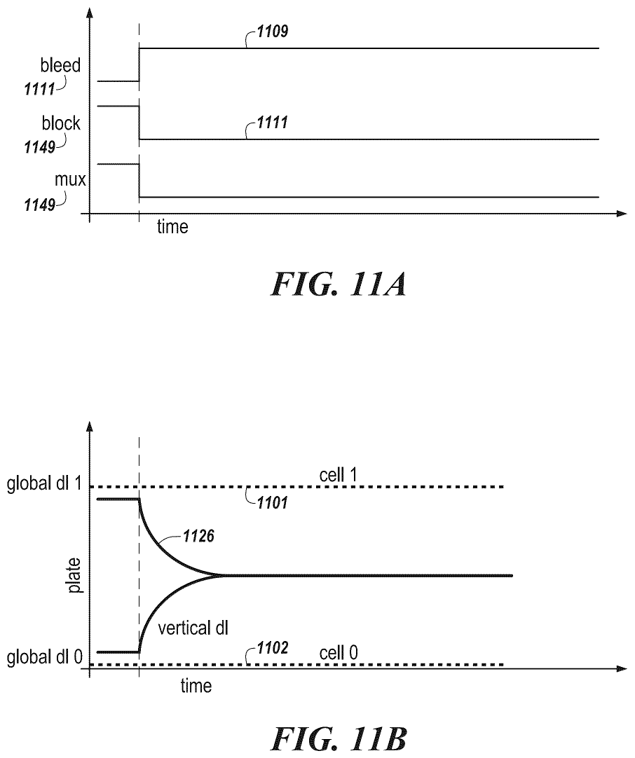

FIGS. 11A and 11B are a timing diagram for a standby operation in a 3D DRAM array having select circuitry for digitline decoupling in accordance with a number of embodiments of the present disclosure. FIG. 12 is a schematic illustration of FIG. 11 showing select circuitry transistor “on”/“off” detail and signal flow operation for digitline decoupling between 3D DRAM array vertical digitline and global digitline to sense latch connection in accordance with a number of embodiments of the present disclosure. As noted above, embodiments include methods for memory operation using select circuitry to decouple a first digitline from a second digitline the through a first digitline multiplexer and a second digitline multiplexer in association with a vertically stacked three-dimensional (3D) dynamic random access memory (DRAM) array.

In FIG. 11A, the timing diagram graph illustrates a change in applied potential to a gate of an access device (control signal), such as a thin film transistor, to enable, e.g., “turn on” signal high, a particular access device, or disable, e.g., “turn off” signal low, the particular access device. As above in FIGS. 11A and 11B, the vertical axis, y-axis, illustrates applied voltage potential level, e.g., magnitude, and the horizontal axis, x-axis, illustrates chronological timing sequence.

In FIG. 11A a change in applied potential, “up” and “down” in magnitude/value, e.g., “high” and “low” signals, is illustrated transitioning from a standing state of the particular applied potential over time, and these applied signals are illustrated in the example for a bleed transistor 1111 control signal, a second digitline multiplexer (“block”) 1149 control signal (e.g., 549 and 649 in FIGS. 5 and 6), and a first digitline multiplexer 1109.

The timing diagram graph of FIG. 11B illustrates a signal magnitude represented as a voltage level on the vertical y-axis, and changes to the signal magnitude over time, chronologically, on the horizontal x-axis corresponding to the upper graph's control signals in association with a write operation.

As shown in FIG. 11A, initially the bleed transistor 1111 is disenabled, e.g., “off”, and restricting a conduction path to ground 1150, e.g. v(plate), for the first digitline 1103, e.g., d1203 in FIG. 12.

Initially as shown in FIG. 11B at 1104, a state placed on or stored to a storage node, e.g., capacitor cells 1230-1, . . . , 1230-N in FIG. 12, is shown as Cell 1 or Cell 0, 1101 or 1102 in FIG. 11B, and is either a “1” or “0” depending on the charge stored on a particular storage node, e.g., information state (“bit”). As shown in FIG. 11A, next at 1125 the first and the second digitline multiplexer 1109 and 1149, as have been described herein, are disabled, e.g., transition down to a “low” state, 1110 and 1115 and the bleed transistor 1111, as has been described herein, is enabled, e.g., transitions up to a “high” state 1129.

Disabling the first digitline multiplexer 1109 and the block transistor 1149, in the “standby” operation allows a state of a memory location may to retain a stored state of “high” or “low” from a previous access, e.g., “write” operation, in the form of a high potential 1101, e.g., a “cell 1”, or in the form of a low potential 1102, e.g., “cell 0”. With the block transistor 1149 disabled, e.g., “off”, the source follower transistor 1119 will be disabled, e.g., off. And with the first digitline multiplexer 1109 and the block transistor 1149 off the first digitline 1103 is decoupled from the second digitline 1105 and there is no connection or conductive pathway between the first digitline 1103 and the second digitline 1105. Enabling the bleed transistor 1111 turns “on” the bleed transistor 1111 and provides a conductive pathway that connects the complementary pair of first digitlines 1126 and 1127 to ground 1150, e.g., v(plate).

As stated above, FIG. 12 is a schematic illustration of an embodiment of the timing diagrams shown in FIGS. 11A and 11B showing select circuitry transistor “on”/“off” detail and signal flow operation for digitline decoupling between a first digitline 1203, e.g., “local” digitline, in a 3D DRAM memory array and a second digitline 1205, e.g., “global” digitline, in the 3D DRAM memory array, the second digitline 1205 being connected to a sense latch 1206, in accordance with a number of embodiments of the present disclosure.

As shown in the schematic embodiment of FIG. 12, disabling the first digitline multiplexer 1109 and the block transistor 1149, in the “standby” operation allows a state of a memory location may to retain a stored state of “high” or “low” from a previous access, e.g., “write” operation, in the form of a high potential 1101, e.g., a “cell 1”, or in the form of a low potential 1102, e.g., “cell 0”. With the block transistor 1149 disabled, e.g., “off”, the source follower transistor 1119 will be disabled, e.g., off. And with the first digitline multiplexer 1109 and the block transistor 1149 off the first digitline 1103 is decoupled from the second digitline 1105 and there is no connection or conductive pathway between the first digitline 1103 and the second digitline 1105. Enabling the bleed transistor 1111 turns “on” the bleed transistor 1111 and provides a conductive pathway that connects the complementary pair of first digitlines 1126 and 1127 to ground 1150, e.g., v(plate). Thus, according to embodiments described herein and shown in FIGS. 11A-12, using select circuitry 1208 to decouple the first digitline 1203 from the second digitline 1205 comprises decoupling the first digitline 1003 from the second digitline 1005 during a standby operation.

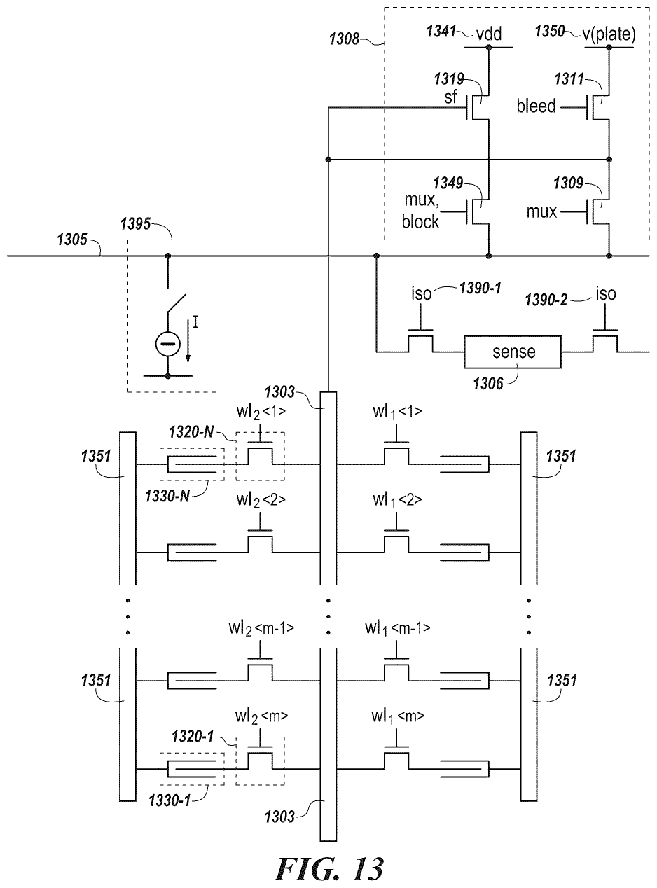

FIG. 13 is a schematic illustration of FIG. 12 having the additional embodiment of having a current generator 1395 connected to the second digitline 1305, e.g., global digitline, and to the sense amplifier latch 1306 of FIGS. 7-12. As shown in FIG. 13, the above described select circuitry 1308 is still used for digitline decoupling between the first digitline 1303 and the second digitline 1305 in the 3D DRAM array in accordance with a number of embodiments of the present disclosure.

The schematic embodiment of FIG. 13 shows select circuitry 1308 detail for digitline decoupling between a vertical, local digitline 1303 and an orthogonal, e.g., horizontal, global digitline 1305 in a 3D DRAM memory array. As shown in FIG. 13, a first digitline 1303 is shared between two adjacent vertical DRAM arrays 1301 and 1302. The shared, vertical first digitline 1303 is connected to source/drain regions (e.g., 321-1, . . . , 321-N of FIG. 3) of access devices, 1320-1, . . . , 1320-N, for memory cells of both adjacent, vertically stacked 3D DRAM arrays 1301 and 1302. As shown in FIG. 13, the vertical first digitline 1303 is connected to and/or decoupled from a second digitline 1306 by select circuitry 1308. According to embodiments, in some memory operations the select circuitry 1308 is used to connect the first digitline 1303 directly to the second digitline 1305, and in other memory operations the select circuitry is used to decouple the first digitline 1303 from the second digitline 1305. For example, in a first memory operation, e.g., a “read” memory operation, the select circuitry 1308 is used to decouple the first digitline 1303 from the second digitline 1305. Instead, using select circuitry 1308, the second digitline 1305 is activated in a decoupled manner through a source follower transistor 1319. The first digitline 1303 is coupled to a gate 1317 of the source follower transistor 1319. In a further example embodiment, in a second memory operation, e.g., a “write” memory operation, the select circuitry is used to connect the first digitline 1303 directly to the second digitline 1305.

As shown in FIG. 13, the select circuitry 1308 can include a first digitline multiplexer 1309 and a bleed transistor 1311. In the example embodiment shown in the schematic illustration of FIG. 13, the first digitline 1303 is connected to a shared first source/drain region 1313 of the first digitline multiplexer 1309 and the bleed transistor 1311. A second source/drain region 1315 of the first digitline multiplexer 1309 is connected to a second digitline 1305. A second source/drain region 1318 of the bleed transistor 1311 can be connected to a ground bias/potential (plate) 1350. In some embodiments, the first digitline 1303 is a vertically oriented, local digitline 1303 and the second digitline 1305 is a horizontally oriented, global digitline 1305.

In the schematic example embodiment of FIG. 13, the select circuitry 1308 further includes a source follower transistor 1319 and a second digitline multiplexer 1349. As shown, the first digitline 1303 is connected to a gate 1317 of the source follower transistor 1319. The source follower transistor 1319 includes a first source/drain region 1331 connected to a first source/drain region 1335, e.g., as a shared source/drain region, of the second digitline multiplexer 1349. A second source/drain region 1337 of the source follow transistor 1319 is connected to a power supply 1341. A second source/drain region 1343 of the second digitline multiplexer 1349 is connected to the second digitline 1305. The second digitline 1305 can be connected to sensing circuitry 1308.

According to some embodiments, as shown in FIG. 13, a current generator 1395 is connected to the second digitline 1305 in a “read” memory operation embodiment to attenuate and/or reject pattern disturb realized and/or derived from adjacent second digitlines 1305. In such embodiments, the second digitline 1305 is statically biased by the source follower transistor 1319 in the select circuitry 1308, and the injected charge during a memory cell read operation is discharged by the current generator 1395. Hence, using embodiments of the select circuitry 1308 and/or current generator 1395 described herein, array efficiency and cost per bit with larger array size in less area and/or longer global digitlines implemented. And the smaller array digitline capacitance can be decoupled from the larger global digitline capacitance. A capacitive coupling ratio between the memory cell and the global digitline can be improved resulting in improvement to read operation signaling magnitude, allowing for longer global digitline connections and relaxed access line thin film transistor (tft) constraints (e.g., more cell leakage may be allowed for a given refresh period). The current generator 1395 embodiments additionally allow for patten noise reduction by biasing the global digitline with a current, e.g., in some embodiments as low as tens of nanoamperes (nA). These benefits prove greater than any tradeoff in increase to the local array digitline pitch.

FIG. 14 illustrates a schematic diagram of a portion of sensing circuitry in accordance with a number of embodiments of the present disclosure. In this example, the portion of sensing circuitry comprises a sense amplifier 1406. In a number of embodiments, one sense amplifier 1406 (e.g., “sense amp”) is provided for each column of memory cells in an array (e.g., array 130). The sense amp 1406 can be sense amp of a DRAM array, for instance. In this example, sense amp 1406 is coupled to a pair of complementary second digitlines 1405-1 (“D”) and 1405-2 (“D_”). As such, the sense amp 1406 is coupled to all of the memory cells in a respective column through digitlines D and D_. As used herein, second digitlines 1405-1 (“D”) and 1405-2 (“D_”) may be referred to as global digitlines, e.g. “global” to an array.

The sense amplifier 1406 includes a pair of cross coupled n-channel transistors (e.g., NMOS transistors) 1427-1 and 1427-2 having their respective sources coupled to a negative control signal 1428 (RNL_) and their drains coupled to digitlines D and D_, respectively. The sense amplifier 1406 also includes a pair of cross coupled p-channel transistors (e.g., PMOS transistors) 1429-1 and 1429-2 having their respective sources coupled to a positive control signal 1431 (PSA) and their drains coupled to digitlines D and D_, respectively.

The sense amp 1406 includes a pair of isolation transistors 1451-1 and 1451-2 coupled to digitlines D and D_, respectively. The isolation transistors 1451-1 and 1451-2 are coupled to a control signal 1422 (ISO) that, when enabled, activates (e.g., turns on) the transistors 1421-1 and 1421-2 to connect the sense amp 1406 to a column of memory cells. Although not illustrated in FIG. 14, the sense amp 1406 may be coupled to a first and a second memory array and can include another pair of isolation transistors coupled to a complementary control signal (e.g., ISO_), which is disabled when ISO is enabled such that the sense amp 1406 is isolated from a first array when sense amp 1406 is coupled to a second array, and vice versa.

The sense amp 1406 also includes circuitry configured to equilibrate the digitlines D and D_. In this example, the equilibration circuitry comprises a transistor 1424 having a first source/drain region coupled to an equilibration voltage 1425 (dvc2), which can be equal to Vcc/2, where Vcc is a supply voltage associated with the array. A second source/drain region of transistor 1424 is coupled to a common first source/drain region of a pair of transistors 1423-1 and 1423-2. The second source drain regions of transistors 1423-1 and 1423-2 are coupled to digitlines D and D_, respectively. The gates of transistors 1424, 1423-1, and 1423-2 are coupled to control signal 1426 (EQ). As such, enabling EQ activates the transistors 1424, 1423-1, and 1423-2, which effectively shorts digitline D to digitline D_ such that the digitlines D and D_ are equilibrated to equilibration voltage dvc2.

The sense amp 1406 also includes transistors 1432-1 and 1432-2 whose gates are coupled to a signal 1433 (COLDEC). Signal 1433 may be referred to as a column decode signal or a column select signal. The digitlines D and D_ are connected to respective input/output lines, e.g., I/O lines 1434-1 (IO) and 1434-2 (IO_) responsive to enabling signal 1433 (e.g., to perform an operation such as a digitline access in association with a read operation). As such, signal 1433 can be enabled to transfer a signal corresponding to the state (e.g., a logic data value such as logic 0 or logic 1) of the memory cell being accessed out of the memory device on the I/O lines 1434-1 and 1434-2.

In operation, when a memory cell is being sensed (e.g., read), the

voltage on one of the digitlines D, D_ will be slightly greater than the voltage on the other one of digitlines D, D_. The PSA signal is then driven high and the RNL_ signal is driven low to enable the sense amplifier 1406. The digitline D, D_ having the lower voltage will turn on one of the PMOS transistor 1429-1, 1429-2 to a greater extent than the other of PMOS transistor 1429-1, 1429-2, thereby driving high the digitline D, D_ having the higher voltage to a greater extent than the other digitline D, D_ is driven high. Similarly, the digitline D, D_ having the higher voltage will turn on one of the NMOS transistor 1427-1, 1427-2 to a greater extent than the other of the NMOS transistor 1427-1, 1427-2, thereby driving low the digitline D, D_ having the lower voltage to a greater extent than the other digitline D, D_ is driven low. As a result, after a short delay, the digitline D, D_ having the slightly greater voltage is driven to the voltage of the PSA signal (which can be the supply voltage Vcc), and the other digitline D, D_ is driven to the voltage of the RNL_ signal (which can be a reference potential such as a ground potential). Therefore, the cross coupled NMOS transistors 1427-1, 1427-2 and PMOS transistors 1429-1, 1429-2 serve as a sense amp pair, which amplify the differential voltage on the digitlines D and D_ and serve to latch a data value sensed from the selected memory cell. As used herein, the cross coupled sense amp pair of sense amp 1406 may be referred to as a sense latch.

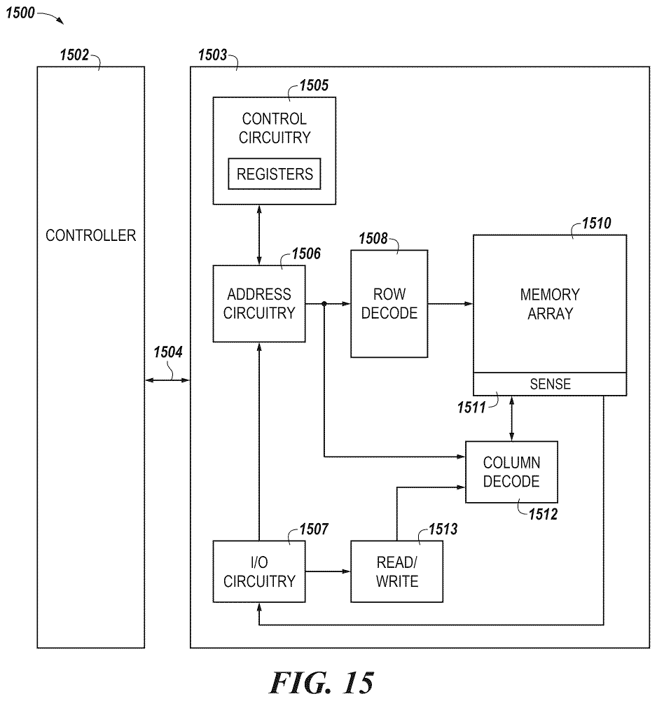

FIG. 15 is a block diagram of an apparatus in the form of a computing system 1500 including a memory device 1503 in accordance with a number of embodiments of the present disclosure. As used herein, a memory device 1503 or a memory array 1510 might also be separately considered an “apparatus.”

System 1500 includes a host (e.g., controller) 1502 coupled to memory device 1503, which includes a memory array 1510. Host 1502 can be a host system such as a personal laptop computer, a desktop computer, a digital camera, a mobile telephone, or a memory card reader, among various other types of hosts. Host 1502 can include a system motherboard and/or backplane and can include a number of processors, microprocessors, or some other type of controlling circuitry. The system 1500 can include separate integrated circuits or both the host (e.g., processor) 1502 and the memory device 1503 can be on the same integrated circuit.

For clarity, the system 1500 has been simplified to focus on features with particular relevance to the present disclosure. The memory array 1510 can be a three-dimensional (3D) dynamic random access memory (DRAM) array, for instance, and can include select circuitry for digitline decoupling as described above in connection with FIGS. 5-13. The array 1510 can comprise memory cells arranged in rows coupled by access lines (which may be referred to herein as word lines or select lines) and columns coupled by sense lines (which may be referred to herein as digitlines or data lines). Although a single array 1510 is shown in FIG. 15, embodiments are not so limited. For instance, memory device 1503 may include a number of arrays 1510 (e.g., a number of banks of DRAM cells). An example DRAM array is described in association with FIG. 4.

The memory device 1510 includes address circuitry 1506 to latch address signals provided over I/O connections 1504 (e.g., a data bus) through I/O circuitry 1507. Address signals are received and decoded by a row decoder 1508 and a column decoder 1512 to access the memory array 1510. Data can be read from memory array 1510 by sensing voltage and/or current changes on the sense lines using sensing circuitry 1511. The sensing circuitry 1511 can read and latch a page (e.g., row) of data from the memory array 1510. The I/O circuitry 1507 can be used for bi-directional data communication with host 1502 over the I/O connections 1504. The read/write circuitry 1513 is used to read data from and write data to the memory array 1531.

Control circuitry 1505 decodes signals provided by control connections 1504 from the host 1502. These signals can include chip enable signals, write enable signals, and address latch signals that are used to control operations performed on the memory array 1510, including data read, data write, and data erase operations. In various embodiments, the control circuitry 1505 is responsible for executing instructions from the host 1502. The control circuitry 1502 can be a state machine, a sequencer, or some other type of controller.

An example of the sensing circuitry 1511 is described in association with FIG. 14. For instance, in a number of embodiments, the sensing circuitry 1511 can comprise a sense amplifier (e.g., sense amplifier 1406 shown in FIG. 14). Select circuity disclosed in connection with FIGS. 5-13 can compensate for source follower mismatch in vertical 3D DRAM read operation and reduce pattern disturb on global digitlines. In this example, the select circuitry can decouple the vertical, first/“local” digitline in the array from the global digitline. Source follower mismatch affects fdw, increasing bit error rate (ber). Because the sense latch reads in a differential manner, with disclosed select circuitry architecture, the two contributions of the source follower threshold on the two different sides of the sense latch will be deleted. The source follower thin film transistor (tft) decouples the small vertical digitline capacitance from the large global digitline capacitance, resulting in a disruptive improvement of the signal. The other select circuitry addition of a second digitline multiplexer, also a tft, connects the source follower transistor to the second digitline, e.g., “global” digitline, and prevents power consumption during the write operation. As described above in connection with FIGS. 5-13, the select circuitry connects the vertical digitline to a gate of the source follower tft and to a shared first source/drain region, e.g., shared “source”, of the first digitline multiplexer and the bleed transistor.

The present disclosure includes vertical 3D DRAM array with digitline decoupling operation, array select circuitry connected to the 3D DRAM array and methods of memory operation relating to read reference setting, read window development, and latch firing. An example memory device comprises a first array of vertically stacked memory cells and a first digitline connected to the access devices in the first array. A second digitline is connected to the first digitline by select circuitry. The select circuitry comprises a first digitline multiplexer and a bleed transistor. The first digitline is connected to a shared first source/drain region of the first digitline multiplexer and the bleed transistor. A second source/drain region of the first digitline multiplexer is connected to the second digitline. The select circuitry further comprises a source follower transistor and a second digitline multiplexer. The first digitline is connected to a gate of the source follower transistor. A first source/drain region of the source follower transistor is connected to a first source/drain region of the second digitline multiplexer. A second source/drain region of the source follower transistor is coupled to a power supply. A second source/drain region of the second digitline multiplexer coupled to the second digitline. Sensing circuitry connected to the second digitline.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and methods are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A memory device, comprising:
a first array of vertically stacked memory cells;
a first digitline connected to the access devices in the first array;
a second digitline connected to the first digitline by select circuitry, the select circuitry, comprising:
a first digitline multiplexer and a bleed transistor, the first digitline connected to a shared first source/drain region of the first digitline multiplexer and the bleed transistor, a second source/drain region of the first digitline multiplexer connected to the second digitline;
a source follower transistor and a second digitline multiplexer, wherein the first digitline is connected to a gate of the source follower transistor, the source follower transistor having a first source/drain region connected to a first source/drain region of the second digitline multiplexer and a second source/drain region coupled to a power supply, a second source/drain region of the second digitline multiplexer coupled to the second digitline; and
sensing circuitry connected to the second digitline.

2. The memory device of claim 1, where the first digitline is a vertically oriented, local digitline and the second digitline is a horizontally oriented, global digitline.

3. The apparatus of claim 1, further comprising:
a second array of vertically stacked memory cells, horizontally adjacent the first array, the first and second array having horizontally oriented access devices and horizontally oriented storage nodes; and
the first digitline is a vertically oriented digitline and is shared between the first and the second arrays and connected to access devices in the first and the second arrays.

4. The memory device of claim 3, wherein:
the first digitline multiplexer and the bleed transistor are positioned vertically above the first array; and
the source follower transistor and the second digitline multiplexer are positioned vertically above the second array.

5. The memory device of claim 4, wherein the source follower transistor and the second digitline multiplexer are thin film transistors.

6. The memory device of claim 1, the memory cells in the first array of vertically stacked memory cells, comprising:
horizontally oriented access devices; and
horizontally oriented storage nodes connected to the horizontally oriented access devices.

7. The memory device of claim 6, wherein the horizontally oriented access devices comprise thin film transistors (tfts) having a gate all around structure (GAA).

8. The memory device of claim 6, wherein the horizontally oriented storage nodes comprise double sided capacitors.

9. The memory device of claim 1, wherein the first digitline is a multilayer, vertical digitline, each layer having a different conductive material composition.

10. The memory device of claim 9, where the first array comprises horizontal access lines.

11. A method for operating a vertically stacked three-dimensional (3D) dynamic random access memory (DRAM) array, comprising:
using select circuitry to decouple a first digitline from a second digitline the through a first digitline multiplexer and a second digitline multiplexer by:
disabling the first digitline multiplexer;
firing a first access line associated with an address in the 3D DRAM array to enable charge sharing from a storage node through an access device to the first digitline, the first digitline connected to a gate of a source follower transistor having a first source/drain region connected to the second digitline multiplexer and a second source/drain region connected to a power supply;
enabling the source follower transistor using a charge shared to the first digitline;
enabling the second digitline multiplexer;
biasing the second digitline by conduction through the source follower transistor and the second digitline multiplexer;
disabling an isolation transistor connecting the second digitline to a sense amplifier to electrically connect the second digitline to the sense amplifier; and
enabling the sense amplifier.

12. The method of claim 11, wherein using select circuitry to decouple the first digitline from the second digitline comprises decoupling the first digitline from the second digitline during a read operation.

13. The method of claim 12, wherein the method comprises coupling a current generator to the second digitline during the read operation.

14. The method of claim 12, wherein using select circuitry to decouple a first digitline from a second digitline, comprising:
disabling the bleed transistor and the second digitline multiplexer; and
enabling the isolation transistor, disconnecting the second digitline from the sense amplifier, during a write operation.

15. The method of claim 12, the method further, comprising:
enabling the bleed transistor; and
disabling the second digitline multiplexer, disabling the source follower transistor, during a standby operation.

16. The method of claim 15, wherein disabling the second digitline multiplexer, disabling the source follower transistor, during the standby operation connect the first digitline to a ground bias (plate).

17. The method of claim 12, wherein using select circuitry to decouple a first digitline from the second digitline comprises decoupling a vertically oriented local digitline in the 3D DRAM array from a horizontally oriented global digitline located above the 3D DRAM array.

18. A method for operating a vertically stacked three-dimensional (3D) dynamic random access memory (DRAM) array, comprising:
using select circuitry to decouple a first digitline from a second digitline the during a first memory array operation, the first memory operation, comprising:
disabling a first digitline multiplexer;
firing a first access line associated with an address in the 3D DRAM array to enable charge sharing from a storage node through an access device to the first digitline, the first digitline connected to a gate of a source follower transistor having a first source/drain region connected to a second digitline multiplexer and a second source/drain region connected to a power supply;
enabling the source follower transistor using a charge shared to the first digitline;
enabling the second digitline multiplexer;
biasing the second digitline by conduction through the source follower transistor and the second digitline multiplexer;
enabling the sense amplifier; and
coupling a current generator to the second digitline; and
using the select circuitry to connect the first digitline to the second digitline the during a second memory array operation, the second memory operation, comprising:
enabling the first digitline multiplexer to connect the second digitline to the first digitline;
disabling a bleed transistor having a shared source/drain region with the first digitline multiplexer;
disabling the second digitline multiplexer to disable the source follower transistor;
firing a first access line associated with an address in the 3D DRAM array to enable charge sharing to a storage node in the array through an access device from the first digitline; and
enabling the sense amplifier.

19. The method of claim 18, further comprising:
performing a memory read operation using the select circuity during the first memory operation; and
performing a memory write operation using the select circuitry during the second memory operation.

20. The method of claim 19, wherein the method comprises connecting the current generator to the second digitline during the memory read operation.

21. The method of claim 20, wherein the method comprises statically biasing the second digitline using the source follower transistor such that a charge injected onto the second digitline from an addressed memory cell is discharged by the current generator connected to the second digitline during a read operation.

22. The method of claim 18, further comprising:
enabling isolation transistors to disconnect the second digitline from a sense amplifier while equilibrating the sense amplifier; and
disabling the isolation transistors to connect second digitline to the sense amplifier during the first and the second memory array operations.
